(19) United States
(12) Patent Application Publication
(10) Pub. No.: US 2023/0345889 A1
(43) Pub. Date: Nov. 2, 2023

(54) MODELING OF SOIL COMPACTION AND STRUCTURAL CAPACITY FOR FIELD TRAFFICABILITY BY AGRICULTURAL EQUIPMENT FROM DIAGNOSIS AND PREDICTION OF SOIL AND WEATHER CONDITIONS ASSOCIATED WITH USER-PROVIDED FEEDBACK

(71) Applicant: DTN, LLC, OMAHA, NE (US)

(72) Inventors: JOHN J. MEWES, Mayville, ND (US); Dustin M. Salentiny, Grand Forks, ND (US)

(21) Appl. No.: 18/094,203

(22) Filed: Jan. 6, 2023

Related U.S. Application Data
(63) Continuation-in-part of application No. 15/049,044, filed on Feb. 20, 2016, now abandoned.
Application No. 15/049,044 is a continuation-in-part of application No. 17/340,774, filed on Jun. 7, 2021, now Pat. No. 11,672,212.
Application No. 17/340,774 is a continuation of application No. 16/179,559, filed on Nov. 2, 2018, now Pat. No. 11,026,376.
Application No. 16/179,559 is a continuation-in-part of application No. 15/883,017, filed on Jan. 29, 2018, now Pat. No. 10,139,797.
Application No. 15/883,017 is a continuation of application No. 15/229,968, filed on Aug. 5, 2016, now Pat. No. 9,880,537.
Application No. 15/229,968 is a continuation-in-part of application No. 16/101,302, filed on Aug. 10, 2018.
(60) Provisional application No. 62/118,615, filed on Feb. 20, 2015.
(60) Provisional application No. 62/201,117, filed on Aug. 5, 2015.
(60) Provisional application No. 62/543,638, filed on Aug. 10, 2017.

(51) Int. Cl. A01G 25/16; G06F 30/20; A01B 79/00; A01G 25/02; G01W 1/10

(52) U.S. Cl. CPC A01G 25/167; G06F 30/20; A01B 79/005; A01G 25/023; G01W 1/10

(57) ABSTRACT

A framework for diagnosing and predicting a suitability of soil conditions to various agricultural operations is performed in a combined, multi-part approach for simulating relationships between predictive data and observable outcomes. The framework includes analyzing one or more factors relevant to field trafficability, workability, and suitability for agricultural operations due to the effects of freezing and thawing cycles, and developing artificial intelligence systems to learn relationships between datasets to produce improved indications of trafficability, workability, and forecasts of suitability windows for a particular user, user community, farm, farm group, field, or equipment. The framework also includes a real-time feedback mechanism by which a user can validate or correct these indications and forecasts. The framework may further be configured to override one or more of the soil state assessments to ensure that indicators and forecasts are consistent with the recently-provided feedback.

### CROSS-REFERENCE TO RELATED APPLICATIONS

This application is a continuation-in-part of:
U.S. patent application Ser. No. 15/049,044, filed Feb. 20, 2016, which claims priority pursuant to 35 U.S.C. 119(e) to U.S. Provisional Patent Application Ser. No. 62/118,615, filed Feb. 20, 2015, the entire disclosures of which are incorporated herein by reference;
U.S. patent application Ser. No. 17/340,774, filed Jun. 7, 2021, which is a continuation of U.S. application Ser. No. 16/179,559, filed Nov. 2, 2018, now U.S. Pat. No. 11,026,376, which is a continuation in part of U.S. patent application Ser. No. 15/883,017, filed Jan. 29, 2018, now U.S. Pat. No. 10,139,797, which is a continuation of U.S. patent application Ser. No. 15/229,968, filed Aug. 5, 2016, now U.S. Pat. No. 9,880,537, which claims priority pursuant to 35 U.S.C. 119(e) to U.S. Provisional Patent Application Ser. No. 62/201,117, filed Aug. 5, 2015, the entire disclosures of which are incorporated herein by reference; and
U.S. patent application Ser. No. 16/101,302, filed Aug. 10, 2018, which claims priority pursuant to 35 U.S.C. 119(e) to U.S. Provisional Patent Application Ser. No. 62/543,638, filed Aug. 10, 2017, the entire disclosure of which is incorporated herein by reference.

### FIELD OF THE INVENTION

The present invention relates to precision agriculture. Specifically, the present invention relates to diagnosing and predicting a suitability of soil conditions to various agricultural operations based at least on field-level weather conditions, together with real-time feedback of observations of current field conditions and soil properties.

### BACKGROUND

Many agricultural activities are substantially affected by weather conditions, and the impact these weather conditions have on soil moisture and temperature conditions. The viability of almost all in-field agricultural operations is dependent upon the soils within the field being adequately firm to support operation of agricultural equipment. This ability of the soil in a field to support such equipment might be referred to as “field trafficability.” For agricultural enterprises concerned with the health of soils, the definition of “adequately firm” refers not only to the ability of a soil to permit access to a field (without the equipment becoming mired in mud, for instance), but also to the ability to support that equipment without significantly compacting the underlying soils. Soil compaction degrades the productivity of soils in several ways, for example by limiting water infiltration capacities, reducing porous space within the root zone (through which the roots of non-hydrophytic plants can acquire necessary oxygen), and by damaging soil structure through the creation of density gradients within the soil that can inhibit healthy penetration and distribution of plant roots.

A related concept of “soil workability” may be defined as how easily the soil is workable, and specifically with respect to agricultural tillage operations. A field that is workable will usually be trafficable as well, but the converse is not always true. Workability is at least a function of the mechanical strength of the soil and soil tilth, both of which relate to complex interactive forces between particles within the soil profile. The magnitude of these forces is dependent upon the inter-particle separation, which is in turn regulated by, among others, soil water content. The optimum soil moisture condition for cultivation also depends on the precise machinery operation involved. Tillage is often used for weed control or residue management, but can also change soil structure. It is generally desirable to produce the greatest proportion of small aggregates with the least amount of deterioration to the overall soil structure. Soil workability has been related to consistency limits of soils such as the liquid limit, plastic limit and shrinkage limit; tests such as the Proctor compaction test, which determines how implements can change the bulk density of the soil as a function of the water content of the soil; and to certain points of the soil water retention curve, such as the field capacity.

Together, trafficability and workability can be thought of generally as accessibility characteristics of a farm field. Although trafficability and workability significantly impact the timeliness of field operations, and hence the productivity of agricultural systems, there is presently no better way of assessing these states of a soil at any given time than from direct field inspections. However, as agricultural operations globally continue to grow in size, the practicality of in-situ monitoring of soil conditions in each field on a regular basis is increasingly diminished. Further, the often substantial equipment and labor resources involved in modern farm operations are not easily moved across significant distances in an effort to find fields with viable soil conditions. Therefore the ability to both diagnose and predict the suitability of soil conditions to various agricultural operations in a potentially remote field is therefore of increasing importance to the management of modern farm operations. Further, production agriculture is often a capital-intensive business with very thin relative profit margins. The ability to more effectively manage the logistics associated with deployment of a farm operation's equipment and human resources is becoming increasingly critical to profitability and long-term viability of the farm itself.

Existing technology uses a range of techniques to diagnose and predict field trafficability and workability to a certain extent. For instance, a simplified bucket model can accumulate rainfall within a field relative to the accumulated evapotranspiration in that same field, where a sufficient accumulation of evapotranspired water can effectively be assumed to have ‘undone’ the impacts of the rainfall on soil conditions within the field. At the other end of the spectrum, a sophisticated soil or land surface model can simulate the individual processes at work in the field, deriving soil temperature and moisture status from base processes given the specific parameters of the field(s) rather than simple buckets. The soil water potentials or moisture deficits in the top layers of the soil in these models can then theoretically be related back to the soil's trafficability and workability properties.

Unfortunately, the critical threshold values around which the trafficability or workability characteristics of a field change must be determined from field experiments, or estimated from known soil physical properties. This data collection requirement has historically limited the practicality of extensive application of such models. Further, while the land surface model products are given straightforward names, interpretation of the underlying variables is anything but straightforward. Even after model-specific treatments of properties such as soil layer depth, texture, porosity, etc., are accounted for, the same moisture variable from two different models—even when driven by the same forcing data—can take on substantially different values. In other words, simulated soil moisture does not have an unambiguous interpretation that can be related to any model-independent thresholds for the determination of workability and/or trafficability. The value of these models lies more in their ability to quantify characteristics of the temporal variability in soil moisture, with the drawing of relationships to observable soil properties left as an altogether separate problem. What the land surface models actually produce are perhaps best thought of as model-specific indices of soil wetness that are expected to be reasonably well-correlated with the true soil moisture values.

Diagnosing or predicting trafficability or workability is also complicated by the spatial variability of soils and soil properties relative to the available soils datasets. Many models have a view of soils that is too simplistic, categorizing them into broad textural classes, and thereby decreasing the accuracy of the models and creating fictitious spatial gradients in soil conditions at the resulting, often-artificial boundaries between input soils data. Further, some of the most important physical properties of the field in terms of how the soils contained therein respond to weather conditions are a function of farming practices. For instance, no-till or low-till farming practices may leave considerable moisture- and heat-trapping residue atop the soil surface. Residue cover on the soil surface results in reduction of the evaporation rate. Farming practices can also substantially alter the organic matter content within the soil profile, which plays an all-important role in defining the structural stability, strength, and water-retention properties of agricultural topsoils, all of which are critical to the workability and trafficability of soils. Artificial surface and sub-surface drainage, often installed to increase the agricultural productivity of the soils within a field, also play substantial roles in the rate of trafficability and workability recovery of soils following a precipitation or irrigation event, and are often unknowable except by direct communication with the owner or farm operator of a particular farm field.

Additionally, on the fringes of a crop growing season, it is not uncommon for soils to freeze during the overnight hours or during spells of cold weather. Frozen soils are every bit as adverse to field workability as excess moisture, and—in the case of frozen soils in the autumn months—can lead to an abrupt or premature end to post-harvest tillage operations (or to the harvest operation itself, if for a root-based crop). Modeling of these processes is also subject to field-level variations in residue, elevation, moisture, and other factors that may not be adequately represented in full in existing models of such freezing and thawing soil cycles.

### SUMMARY

It is therefore one objective of the present invention to provide systems and methods of diagnosing and predicting soil conditions for conducting various agricultural operations. It is another objective of the present invention to assess a soil state to evaluate field accessibility and suitability for agricultural activity. It is a further objective of the present invention to model one or both of soil moisture and soil temperature, and the impact on field access for whether a field is trafficable and workable. It is still another objective of the present invention to forecast temporal windows of opportunity for suitability of agricultural activity from models of anticipated freezing and thawing cycles in soils.

It is another objective of the present invention to provide a system and method of evaluating data that includes soil, field, crop, and weather information to diagnose and predict soil conditions using a multi-part approach that includes physical models, artificial intelligence systems, and real-time user feedback. It is still another objective of the present invention to translate weather data, together with related crop and field characteristics, and an expected soil condition response thereto to model one or more of soil moisture and soil temperature for the impact on field access for whether a field is trafficable and workable.

Recent parallel advances in weather and soil condition analysis and prediction, and in the availability of mechanisms for facilitating real-time and location-tagged data communication in farm operations, create an enticing set of possible new applications for addressing the problems outlined above. The application of both in-situ (though not necessarily in or near a particular field) and remotely-sensed weather information, in combination with advances in scientific and computational integration of data collected by these disparate weather observing systems, permit the diagnosis of field-level weather conditions with accuracy that may be equal to or better than what could be obtained with the deployment of a basic weather station to each and every field. Further, advances in the understanding of the interactions between the land surface and the overlying atmosphere, combined with other improvements to the physics of meteorological weather models, and the ever-increasing computational power available to operate these models at finer resolutions, are providing for a level of both short- and long-term accuracy and locality to weather forecasts that has not been previously attainable.

When applied to models for diagnosing and predicting the soil conditions in a farm field, the prospects for providing improved guidance relating to agricultural operations are substantial. One prominent class of models for the simulation of soil conditions is referred to collectively as land surface models (LSM). Land surface models simulate the processes that take place at the interface between the surface of the Earth and its overlying atmosphere. Commonly-used land surface models include the NOAH community land surface model, the VIC (or Variable Infiltration Capacity) model, the Mosaic model, and the CLM (or Community Land Model). Numerous other land surface models are available for both research and commercial applications. Land surface model inputs include soil composition and characteristics, vegetation characteristics, various relationships and characteristics defining the soil-water-plant relationships, detailed weather information (including detailed precipitation and radiation information), among many other things.

Although the sophistication and accuracy of these models continues to increase over time, the aforementioned limitations of existing approaches (inter-model variability in similar variables, variability in key thresholds of soil properties relating to workability and trafficability, the impact of farming practices on soil conditions, drainage systems, the specific crop and growth stage, etc.) continue to keep the potential benefits from being realized. Further, the impacts of soil conditions on farm operations can be heavily influenced by the specific operations and implementations that are to be performed at any given time. For instance, equipment with substantial areas of soil contact (more or larger tires, or tracks) relative to the equipment's weight will permit trafficability at higher moisture levels than might be the case for equipment without these characteristics. Likewise, some field operations—such as tillage, sowing and planting—are highly-dependent upon the field workability, whereas others—such as pesticide applications—may not be. Planting of many crops in particular can be extremely sensitive to soil moisture conditions, as even a very light rainfall can make the soil surface sticky, leading to a buildup of mud on the gauge wheels that control seed depth and result in seeds being placed at a lesser depth than would be desirable.

A potential solution to these longstanding issues is afforded to the agricultural community by now near-ubiquitous presence of real-time data collection and management platforms in modern farm operations. It is now possible to collect previously-lacking information, so that for example, modern farm management software, systems and instruments can be leveraged to collect, store and share information concerning field properties and the more-changeable crop and crop residue characteristics. This information permits more accurate configuration of land surface models, leading to more accurate model diagnoses and forecasts of soil conditions.

These additional inputs improve the accuracy of land surface model outputs, but they do not in themselves address all of the issues that hinder the realization of potential benefits to the agricultural industry. Modeling of the many of the processes at work at this land-atmosphere interface are further improved by applying additional modeling steps, such as training one or more layers of artificial intelligence to continually analyze the various inputs for a further understanding of the relationships between the available model outputs and the trafficability/workability of a particular field (or area within a field) given a particular set of equipment and the intended activity. These are among the further problems addressed by the present invention.

Other objects, embodiments, features, and advantages of the present invention will become apparent from the following description of the embodiments, taken together with the accompanying drawings, which illustrates, by way of example, the principles of the invention.

The foregoing and other objects are intended to be illustrative of the invention and are not meant in a limiting sense. Many possible embodiments of the invention may be made and will be readily evident upon a study of the following specification and accompanying drawings comprising a part thereof. Various features and subcombinations of invention may be employed without reference to other features and subcombinations. Other objects and advantages of this invention will become apparent from the following description taken in connection with the accompanying drawings, wherein is set forth by way of illustration and example, an embodiment of this invention and various features thereof.

### BRIEF DESCRIPTION

A preferred embodiment of the invention, illustrative of the best mode in which the applicant has contemplated applying the principles, is set forth in the following description and is shown in the drawings and is particularly and distinctly pointed out and set forth in the appended claims.

The accompanying drawings, which are incorporated in and constitute a part of this specification, illustrate several embodiments of the invention and together with the description, serve to explain the principles of the invention.

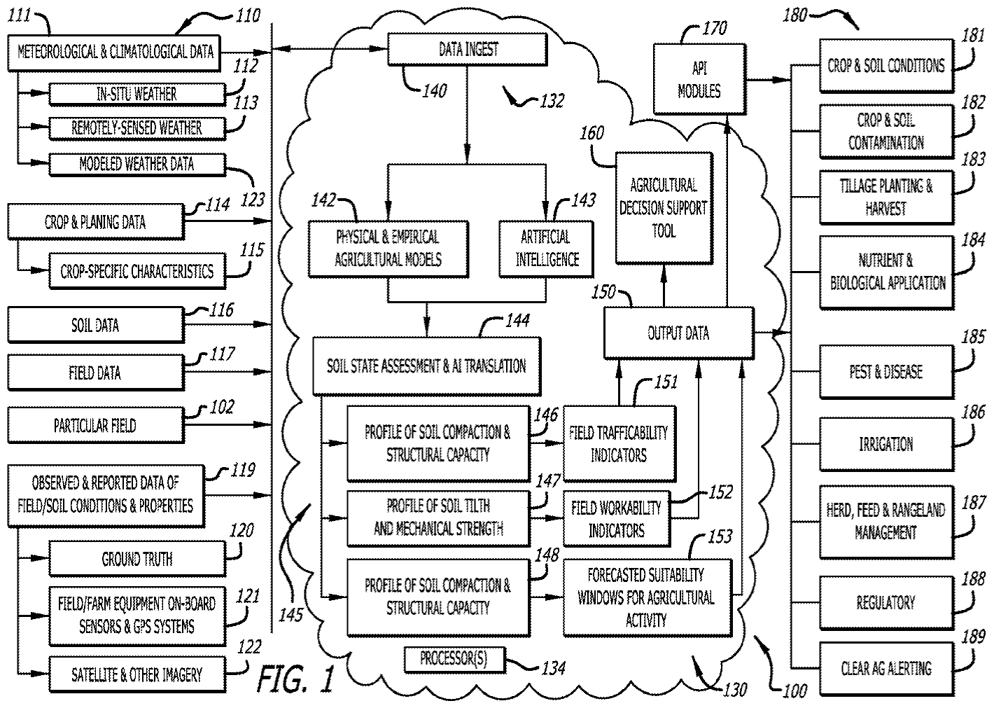

FIG. 1 is a block system architecture diagram of various components of a field accessibility modeling framework according to the present invention;

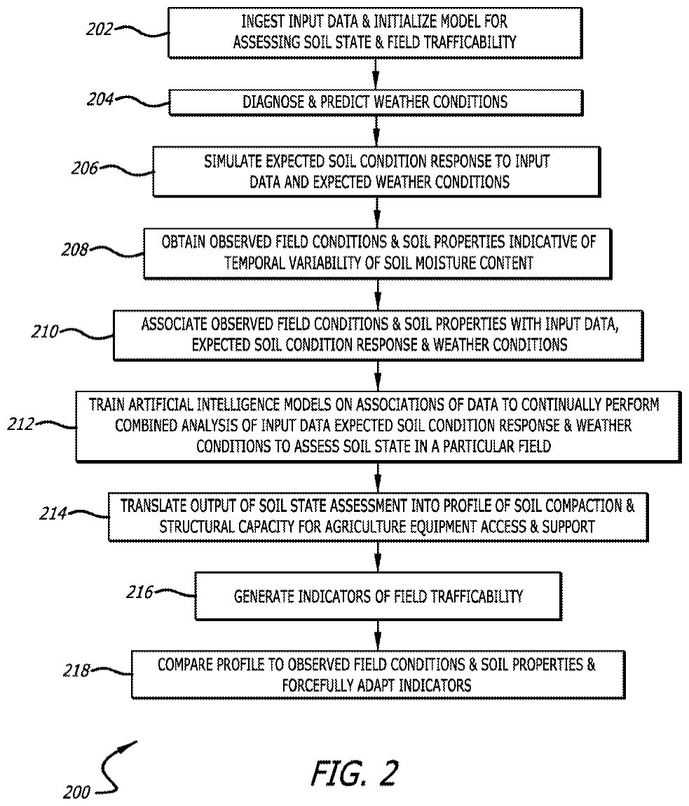

FIG. 2 is a flow diagram of a process for assessing soil state for field trafficability according to one aspect of the present invention;

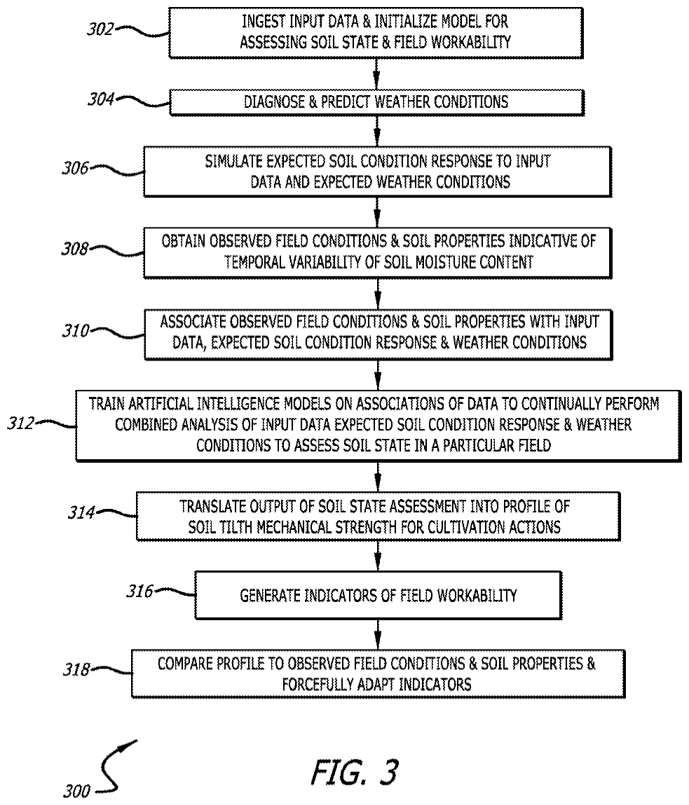

FIG. 3 is a flow diagram of a process for assessing soil state for field workability according to another aspect of the present invention; and

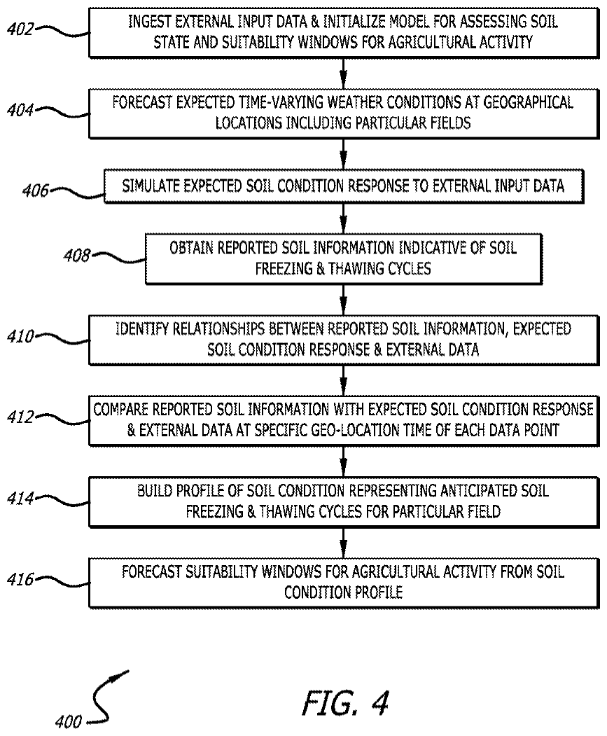

FIG. 4 is a flow diagram of a process for assessing soil state for forecasting windows of suitability for agricultural activity according to another aspect of the present invention.

APPENDIX A includes U.S. Patent Publication No. 2016/0247079, which is the publication of U.S. patent application Ser. No. 15/049,044 directed to MODELING OF SOIL COMPACTION AND STRUCTURAL CAPACITY FOR FIELD TRAFFICABILITY BY AGRICULTURAL EQUIPMENT FROM DIAGNOSIS AND PREDICTION OF SOIL AND WEATHER CONDITIONS ASSOCIATED WITH USER-PROVIDED FEEDBACK.

APPENDIX B includes U.S. Patent Publication No. 2021/0289723, which is the publication of U.S. patent application Ser. No. 17/340,774 directed to CUSTOMIZED LAND SURFACE MODELING FOR IRRIGATION DECISION SUPPORT FOR TARGETED TRANSPORT OF NITROGEN AND OTHER NUTRIENTS TO A CROP ROOT ZONE IN A SOIL SYSTEM.

APPENDIX C includes U.S. Patent Publication No. 2019/0050510, which is the publication of U.S. patent application Ser. No. 16/101,302 directed to DEVELOPMENT OF COMPLEX AGRICULTURAL SIMULATION MODELS FROM LIMITED DATASETS.

The drawing figures do not limit the present invention to the specific embodiments disclosed and described herein. The drawings are not necessarily to scale, emphasis instead being placed upon illustrating the principles of the invention.

### DETAILED DESCRIPTION

As required, a detailed embodiment of the present invention is disclosed herein; however, it is to be understood that the disclosed embodiment is merely exemplary of the principles of the invention, which may be embodied in various forms. Therefore, specific structural and functional details disclosed herein are not to be interpreted as limiting, but merely as a basis for the claims and as a representative basis for teaching one skilled in the art to variously employ the present invention in virtually any appropriately detailed structure.

In the following description of the present invention, reference is made to the exemplary embodiments illustrating the principles of the present invention and how it is practiced. Other embodiments will be utilized to practice the present invention and structural and functional changes will be made thereto without departing from the scope of the present invention.

The present invention is a field accessibility modeling framework 100 for performing assessments of a soil state, and diagnosing and predicting a suitability of soil conditions to various agricultural operations from such assessments. This field accessibility modeling framework 100 presents multiple approaches for simulating relationships between predictive data, various crop and observable outcomes, and is embodied in one or more systems and methods that at least in part include a model that analyzes weather information, together with soil, crop and field characteristics, to assess whether a field is accessible, at least in terms of whether a field is trafficable and also whether a field is workable. The multiple approaches include physical models, artificial intelligence processes, and real-time user feedback to provide one or outputs representative of such field trafficability and workability as well as suitability for agricultural activity owing to specific soil states such as frozen, freezing, and thawing soils.

FIG. 1 is a systemic architecture diagram indicating various components and flow of information in the field accessibility modeling framework 100. The present invention performs the various functions disclosed herein to model characteristics of a particular field 102 for conducting agricultural activity, such as whether a field is trafficable, whether a field is workable, and whether a field is suitable for agricultural activity with an understanding of freezing and thawing cycles expected in the soil.

In the present invention, various types of input data 110 are applied to a plurality of data processing modules 132 within a computing environment 130 that also includes one or more processors 134 and a plurality of software and hardware components. The one or more processors 134 and plurality of software and hardware components are configured to execute program instructions or routines to perform the functions described herein, and embodied within the plurality of data processing modules 132.

The field accessibility modeling framework 100 performs these functions by ingesting, retrieving, requesting, receiving, acquiring or otherwise obtaining the input data 110 to initialize the modeling paradigms and profile soil conditions, from which the indicators and windows of suitability comprising the output data 150 are generated, described further herein. The input data 110 includes meteorological and climatological data 111 which is comprised of one or more of in-situ weather data 112, remotely-sensed weather data 113, and modeled weather data 123, and may further include other current-field level weather data, extended-range weather data, and historical, recent, current, predicted, and forecasted weather conditions, from a variety of different sources. This meteorological and climatological data 111 is used to profile expected weather conditions for the particular field 102 to diagnose, predict and forecast expected weather conditions impacting soil conditions in a particular field 102, and/or in one or more geographical locations that may include the particular field 102. Alternatively weather information in the meteorological and climatological data 111 may be applied to one or more weather models 141 to generate such a profile, and/or diagnose, predict, or forecast localized weather conditions.

Input data 110 also includes crop and planting data 114, comprised of crop-specific characteristics 115 that play an impactful role in temporal variations soil moisture content, soil temperature, and soil conditions generally. Crop-specific characteristics 115 include, for example crop type, seed type, planting data, growing season data and projections, projected harvest date, crop temperature, crop moisture, seed moisture, plant depth, and row width. Crop-specific characteristics 115 may further include any other crop and plant information that may be modeled within the present invention to formulate the output data 150. Crop and planting data 114 may be provided from many different sources, such as for example as output data from one or more of phenology models of crop and plant growth, and other methods of predicting crop and plant growth over the course of a growing season, such as continual crop development profiling of the like disclosed in U.S. Pat. No. 9,131,644. Similarly, harvest data may be provided as output data from one or more models of harvestability, such as those disclosed in U.S. Pat. No. 9,076,118. Crop and planting data 114 may be provided from growers or landowners themselves (or other responsible entities), from crop advisory tools, from farm equipment operating in a field, and any other source of such information.

Input data 110 may also include soil data 116. Examples of soil data 116 include soil type, soil porosity, soil pH, soil profile, and mineral content, such as for example its sodicity. Soil data 116 may likewise be imported from many different sources. Soil data 116 may be imported from one or more external database collections, such as for example the USDA NRCS Soil Survey Geographic (SSURGO) dataset that contains background soil information as collected by the National Cooperative Soil Survey over the course of a century, or from one or more models configured to profile soil structure and composition. Soil data 116 may also be provided from growers or landowners themselves (or other responsible entities), from soil advisory tools, from farm equipment operating in a field, and any other source of such information.

Input data 110 may also include field data 117 that includes various field characteristics, such as field-specific location data 118, and crop-agnostic management actions. Field-specific location data 118 identifies a particular field 102 for analysis within the field accessibility modeling framework 100, and may include GPS information such as positional coordinates, and other data enabling a simulation of a soil response in the particular field 102 to expected weather conditions. Crop-agnostic management actions may include historical or recent tillage practice, such as the type of tillage employed and equipment used. Treatments applied to the field may also be included in the field data 117, as well as a history of crops and seeds planted in prior growing seasons. Field data 117 may further include water information such as groundwater, watershed and aquifer data, and information on prior and recent irrigation practice.

Input data 110 may further include recent or real-time observations and reported data of field conditions and soil properties 119. This information 119 serves as user-provided feedback for the field accessibility modeling framework 100 that represents current, actual, and/or real-time field and soil data, and may be provided by many different sources. Such sources include ground truth or in-situ assessments 120 of field conditions and soil properties, which may be provided by users as real-time, in-field measurements. Other sources include sensors 121 that are configured on-board field and farm equipment to collect and transmit data representative of field conditions and soil properties and weather conditions, and on-board GPS systems 121 that are also configured on field and farm equipment. Observations and reported data of field conditions and soil properties 119 may also be acquired from analysis of imagery data 122, such as remotely-sensed satellite imagery data and remotely-captured drone imagery data captured from orbiting satellites or remotely-powered vehicles that provide details at a field-level resolution when processed. Other sources of imagery data 122 may include image-based data derived from systems such as video cameras configured on-board farm and field equipment.

It is to be understood that observations and reported data of field conditions and soil properties 119 ingested into the present invention may include one or more of actual measurements of real-time, experienced field/soil conditions, crowd-sourced (anonymous or identified) observational data, vehicular data, and image-based data. Vehicular data, as suggested above, may be generated from one or more vehicle-based sensing systems, including those systems coupled to computing systems configured on farm equipment, or those systems configured to gather weather, field and soil conditions from mobile devices present within vehicles, such as with mobile telephony devices and tablet computers. Input data 110 may also be provided by crowd-sourced observations, for example growers, farmers and other responsible entities using mobile telephony devices or tablet computers, or any other computing devices, that incorporate software tools such as mobile applications for accessing and using social media feeds. Regardless of the source, the present invention contemplates that observations and reported data of field conditions and soil properties 119 are indicative of a temporal variability of soil moisture content, and have impact on one or more of soil compaction and structural capacity for access to and support for agricultural equipment, soil tilth and soil mechanical strength, and conditions that produce freezing and thawing cycles in soils.

The plurality of data processing modules 132 include a data ingest component 140, which is configured to perform the ingest, retrieval, request, reception, acquisition or obtaining of input data 110, and initialize the various modeling paradigms disclosed herein for assessing a soil state and translating the outputs of additional components for output data 150 described herein. The data ingest component 140 may therefore determine additional input data 110 needed for the various modeling paradigms, for example by analyzing positional coordinates of a particular field 102 from the field-specific location data 118, and may issue one or more requests for additional input data 110.

The plurality of data processing components 132 may also include the one or more weather models 141, configured to further model the meteorological and climatological data 111 for analyze expected weather conditions that impact soil conditions in a particular field 102. Localized weather conditions may be profiled from the meteorological and climatological data 111 to diagnose, predict, or forecast expected weather conditions at one or more geographical locations that include a particular field 102, and meteorological and climatological data 111 may be applied to such weather models 141 to further analyze weather conditions as part of the modeling paradigms disclosed herein.

It is contemplated that the field accessibility modeling framework 100 may apply weather information in meteorological and climatological data 111 that is derived or obtained from many different sources. Such sources of may include data from both in-situ and remotely-sensed observation platforms. For example, numerical weather models (NWP) and/or surface networks may be combined with data from weather radars and satellites to reconstruct the current weather conditions on any particular area to be analyzed. There are numerous industry NWP models available, and any such models may be used as sources of meteorological information in the present invention. Examples of NWP models at least include RUC (Rapid Update Cycle), WRF (Weather Research and Forecasting Model), GFS (Global Forecast System) (as noted above), and GEM (Global Environmental Model). Meteorological information is received in real-time, and may come from several different NWP sources, such as from Meteorological Services of Canada's (MSC) Canadian Meteorological Centre (CMC), as well as the National Oceanic and Atmospheric Administration's (NOAA) Environmental Modeling Center (EMC), and many others. Additionally, internally or privately-generated “mesoscale” NWP models developed from data collected from real-time feeds to global observation resources may also be utilized. Such mesoscale numerical weather prediction models may be specialized in forecasting weather with more local detail than the models operated at government centers, and therefore contain smaller-scale data collections than other NWP models used. These mesoscale models are very useful in characterizing how weather conditions may vary over small distances and over small increments of time. The present invention may be configured to ingest or otherwise obtain data from all types of NWP models, regardless of whether publicly, privately, or internally provided or developed.

Other sources of meteorological and climatological data 111 may include image-based data from systems such as video cameras, and data generated from one or more vehicle-based sensing systems, including those systems coupled to computing systems configured on farm equipment, or those systems configured to gather weather data from mobile devices present within vehicles, such as the mobile telephony devices and tablet computers as noted above. Crowd-sourced observational data may also be provided from farmers using mobile telephony devices or tablet computers using software tools such as mobile applications, and from other sources such as social media feeds. Meteorologist input may be still a further source of data.

One source of image-based data may be satellite systems that provide remotely-sensed imagery, such as fine temporal resolution low-earth orbit satellites that provide a minimum of three spectral bands. Other sources are also contemplated, such as for example unmanned aerial or remotely-piloted systems, manned aerial reconnaissance, lower temporal frequency earth resources satellite such as LANDSAT and MODIS, ground-based robots, and sensors mounted on field and farm equipment.

The field accessibility modeling framework 100 ingests all of this input data 110 and applies it to one or more agronomic models 142 and to one or more layers of artificial intelligence models 143, to produce a plurality of soil condition profiles 145 from soil state assessment module 144 which are used to generate output data 150. The output data 150 of the field accessibility modeling framework 100 is represented in one or more of indicators of field's trafficability 151, indicators of a field's workability 152, and forecasted suitability windows for agricultural activity 153 that may be provided to a precision agricultural decision support tool 160 that can be used to further predict, simulate, and forecast soil conditions and other output information.

The one or more agronomic models 142, together with the layer of artificial intelligence models 143, enable the field accessibility framework 100 to develop relationships between the various types of input data 110 to perform the soil state assessments in module 144 that is used to formulate the profiles 145. The agronomic models 142 analyze one or more physical and empirical characteristics impacting soil conditions in a particular field 102. Such models 142 include crop, soil, plant, and other modeling paradigms, such as for example phenological models that include general crop-specific and crop variety-specific models, a common example being growing degree day (GDD) models. These models 142 may also include soil models such as the EPIC, APEX, and ICBM soil models, and land surface models such as the NOAH, Mosaic, and VIC models. Other models contemplated within the scope of the present invention include crop-specific, site-specific, and attribute-specific physical models. It is contemplated that the input data 110 may be applied to existing precision agriculture models, as well as customized models for specific soil or field conditions.

The present invention employs such models 142 for simulating agronomic problems and processes of interest to the agricultural community because they are able to provide insight into the outcomes likely to be experienced by agricultural producers. When applied to models for diagnosing and predicting the soil conditions in a farm field, the prospects for providing improved guidance relating to agricultural operations are substantial.

As noted above, land surface models are one prominent class of models for the simulation of soil conditions. Land surface models simulate the processes that take place at the interface between the surface of the Earth and its overlying atmosphere. Such simulations of soil conditions include, but are not limited to simulation of runoff and infiltration of precipitation off of or into the soil profile; drainage, vapor diffusion, capillary action, and root uptake of moisture within any number of layers within a soil profile; vertical diffusion and conduction of internal energy (heat) into, out of, and within the soil profile; plant growth and transpiration, including the impacts of weather and soil conditions on the properties and processes of this vegetation; and direct exchanges of moisture between the atmosphere and the soil (and plant) surfaces via evaporation, sublimation, condensation and deposition, among other processes.

Examples commonly-used land surface models include the NOAH community land surface model, originally developed jointly by the National Centers for Environmental Prediction (NCEP), the Oregon State University (OSU), the United States Air Force, and the National Weather Service's Office of Hydrology (OH); the VIC model, or Variable Infiltration Capacity model, developed by the University of Washington's Land Surface Hydrology group; the Mosaic model, developed by the National Aeronautics and Space Administration (NASA); and the CLM model, or Community Land Model, a collaborative project between divisions and groups within the National Centers for Atmospheric Research (NCAR).

It is to be understood that there are many types of land surface models available, and contemplated as within the scope of the present invention. Additionally, more than one land surface model may be employed, and the agronomic models 142 may apply land surface models in combination with other agricultural models. Therefore, the present invention is not to be limited by any one agronomic model referenced herein.

Regardless of the type of agronomic model 142 applied, the field accessibility modeling tool 100 is configured to utilize such models 142 to simulate an expected soil response to information comprised of the input data 110 and the diagnosed, predicted, and/or forecasted weather conditions for the particular field 102. This simulation of expected soil response is further applied to the layer of artificial intelligence 143, which is trained to associate and compare the various types of input data 110 and identify relationships in such input data 110 in a combined analysis that produces the soil state assessment 144 and translation of artificial intelligence output into the profiles 145.

The present invention contemplates that these relationships may be identified and developed in such a combined analysis by training the layer of artificial intelligence 143 to continually analyze to input data 110 using the observed and reported data of field conditions and soil properties 119. The artificial intelligence module 173 may use this observed and reported data of field conditions and soil properties 119, together with the associated input data 110, to build a more comprehensive dataset that can be used to make far-reaching improvements to the agronomic models 142 of physical and empirical characteristics for diagnosing and predicting the underlying soil condition. For instance, the artificial intelligence layer 143 can be applied to an adequately-sized dataset to draw automatic associations and identify relationships between the available external data and the soil condition, effectively yielding a customized model for simulating the soil condition in a particular field 102. As more and more data are accumulated, the information can be sub-sampled, the artificial intelligence layer 143 retrained, and the results tested against independent data in an effort to find the most reliable agronomic model 142. Further, such modeling implicitly yields information as to the importance of related factors through the resulting weighting systems between inputs, subcomponents within the artificial intelligence layer 143, and the output(s). This information may be used to identify which factors are particularly important or unimportant in the associated process, and thus help to target ways of improving the agronomic model 142 over time.

The present invention contemplates that many different types of artificial intelligence may be employed within the scope thereof, and therefore, the artificial intelligence layer 143 may include one or more of such types of artificial intelligence. The artificial intelligence modeling layer 143 may apply techniques that include, but are not limited to, k-nearest neighbor (KNN), logistic regression, support vector machines or networks (SVM), and one or more neural networks. Regardless, the use of artificial intelligence in the field accessibility modeling framework 100 of the present invention enhances the utility of physical and empirical agronomic models 142 by automatically and heuristically constructing appropriate relationships, mathematical or otherwise, relative to the complex interactions between soils and growing and maturing plants, the field environment in which they reside, the underlying processes and characteristics, and the observational input data 119 made available. For example, where predictive factors known to be related to a particular outcome are known and measured along with the actual outcomes in real-world situations, artificial intelligence techniques are used to ‘train’ or construct a model 142 that relates the more readily-available predictors to the ultimate outcomes, without any specific a priori knowledge as to the form of those relationships.

The present invention therefore adopts a combined modeling approach for simulating the relationships between input data 110, predictive data and eventual outcomes, and may be thought of as performing one or more customized models for assessing soil state, and for generating the indicators and forecasts for agricultural activity comprising the output data 150 for a particular field 102. In the field accessibility modeling framework 100, this approach permits the better-understood portions of the problem at hand to be modeled using a physical or empirical agronomic model 142, while permitting the less well understood portions of the potential issues in the particular field 102 to be automatically modeled based on the relationships implicit in the particular input data 110 provided to the system. In additional embodiments, with sufficient input data and output reliability and accuracy, the physical agronomic models 142 may be entirely supplanted by the use of artificial intelligence model(s) 143. Alternatively, the artificial intelligence layer need not be employed in the system to produce the desired output information.

The physical and empirical agronomic models 142 and one or more artificial intelligence components 143 together process the input data 110 to perform a soil state assessment and translation 144 to produce profiles 145 of soil conditions, as output of the soil state assessment and artificial intelligence translation module 144. One such profile 145 is a profile of soil compaction and structural capacity 146, which relates to soil health and a field's ability to permit access to various equipment without becoming mired, for instance, in mud, as well as the ability to support that equipment without significantly compacting the underlying soils after equipment has accessed the field.

This aspect of a soil's condition is at least in part a function of a temporal variabilities in soil moisture and may also be a function of additional aspects of a soil's state, such as for example soil temperature. Regardless, such a characteristic of the soil changes throughout the year at least by expected weather conditions, tillage, sowing, planting, harvesting and other cultivation actions, by nutrients and chemical treatments applied to the soil, and from artificial precipitation applied to the soil. These variabilities profoundly impact a field's trafficability on a constant basis, and growers, landowners, and other entities and users benefit from a finely-tuned, updated analysis of the ability of the field and soil to support equipment throughout the year from the combined modeling approach of the present invention.

As noted above, the field accessibility modeling tool 100 translates the output of the combined modeling approach described above to produce the profile 146 in soil state assessment and translation module 144. The profile 146 is then converted into one or more field trafficability indicators 151, which are used by growers, landowners, and other responsible entities and users to determine, plan and carry out activity using farm equipment. The indicators 151 may be in a variety of forms, and may include a numerical value representing field trafficability, a non-numerical index of field trafficability, and an indicator of soil suitability for agricultural equipment in the particular field.

The field trafficability indicators 151 may further comprise an indicator of a risk of soil compaction, an indicator of soil temperature over time, and an indicator of soil moisture content over time. Additional field trafficability indicators 151 may include an indicator of soil productivity degradation from a compaction of soil, and an indicator of soil structure damage from excessive density inhibiting plant root penetration and distribution.

The soil state assessment and translation 144 module also generates a profile of soil tilth and mechanical strength 147, which relates to interactions between particles within the various horizons comprising a soil's profile, and a soil's resulting capacity for particular cultivation activities such as tillage, sowing, planting, harvesting actions, nutrients and chemical applications, and artificial precipitation. This aspect of a soil's condition is also at least in part a function of a temporal variabilities in soil moisture and may also be a function of additional aspects of a soil's state, such as for example soil temperature.

Tilth refers to a physical condition of soil and is strongly associated with its suitability for planting or growing a crop. Factors that determine tilth include the formation and stability of aggregated soil particles, moisture content, degree of aeration, rate of water infiltration and drainage. Soil tilth changes rapidly, and the rate of change depends on environmental factors such as changes in moisture, tillage and additives or treatments that are applied to soil. Wet soils will have poor tilth, as they are lacking air space in the soil voids. Aggregates present in wet soil—such as small clods of dirt—are easily broken down by field operations. Destruction of such aggregates reduces the void space in the soil, thereby reducing the soil's capacity to hold both air and water. Further, when these aggregates are broken down by working a wet soil, the finer particles that result are more easily glued together into large clods as they dry. These clods tend to be hard for roots to infiltrate, reducing the capacity of the crop to extract both water and nutrients from the soil.

Regardless, and like a field's trafficability, the workability of the soil changes throughout the year at least by expected weather conditions, and the various activities that are performed in the field. These variabilities profoundly impact a field's workability on a constant basis, and growers, landowners, and other entities and users benefit from a finely-tuned, updated analysis of the ability of the field and soil to perform cultivation actions that take place throughout the year from the combined modeling approach of the present invention.

The profile 147 is generated by the soil state assessment and artificial intelligence translation module 144, and is converted into one or more field workability indicators 152, which are used by growers, landowners, and other responsible entities and users to determine, plan and carry out various cultivation actions. The indicators 152 may be in a variety of forms, and may include a numerical value representing field workability, a non-numerical index of field workability, and an indicator of soil suitability for cultivation actions in the particular field 102. Cultivation actions include a wide range of activities, such as tillage, irrigation, sowing, seeding, planting, nutrient application, chemical application, mechanical weed control, cutting, windrowing and harvesting.

The field workability indicators 152 may further comprise an indicator of soil conditions for maintenance of a soil structure, an indicator of soil temperature over time, and an indicator of soil moisture content over time. Other possible indicators 152 include an indicator of effectiveness of a cultivation action, an indicator of agricultural productivity for a specified crop, an indicator of consistency limits of soil, and an indicator of bulk density of soil.

Another profile 145 generated by the soil state assessment and artificial intelligence translation module 144 is a profile of soil conditions 148 that represents anticipated soil freezing and thawing cycles for the particular field 102 on a current day and on one or more future days. The field accessibility modeling framework 100 models the input data 110 and observed and reported data 119 that are indicative of soil freezing and thawing cycles, to predict soil temperatures and the processes of freezing and thawing of soils in layers throughout the depth of the soil profile. The combined approach of the present invention models this data by comparing a plurality of data points representing a suitability of soil for agricultural activity during the freezing and thawing cycles in one or more temporal windows. The observed and reported data 119 represents field-level variations in residue, elevation, moisture, and other factors, and enables comparisons with at least one of the expected soil response and the external data at the specific location and time of each data point.

The soil conditions profile 147 is generated by the soil state assessment and artificial intelligence translation module 144, and is converted into one or more forecasts 153 of temporal windows of suitability for agricultural activity owing to the anticipated freezing and thawing cycles. These forecasts 153 may be fine-tuned to create advisories or customized forecasts for a current day or specific future days, and may be further customized by matching the one or more windows of suitability to a specific field, a specific crop, a specific item of agricultural equipment, or a specific agricultural activity for a specific day. Such fine-tuned or customized forecasts 153 may be generated using the agricultural decision support tool 160, or as advisories 180 directly from the output data 150 or through one or more API modules 170.

The data processing components may further include a forced adaptation module configured to compare each profile 145 to observed and reported data of field conditions and soil properties 119, and force the resulting indicators and forecasts to temporarily or permanently adapt thereto for a specified period of time. In other words, were a comparison of a profile 145 (and/or, an indicator 151, 152, or forecast 153) to the observed and reported data 119 indicates a variance that exceeds a specified threshold, the present invention may force the profile 145 and/or indicators to match the feedback portion of the input data 110 representative or real-time or actual conditions.

Such a comparison is beneficial, as even as the artificial intelligence systems increasingly evolve to offer personalized trafficability or workability models, situations inevitably arise where the outputs of these systems are not in agreement with the current observation of field conditions. This may be the case even after a feedback pair associated with the current observation has been submitted and accounted for in the retrained artificial intelligence systems. In order to continue to promote a sense that the system is responsive to the user's feedback, the present invention may include applying logic in such a forced adaptation module to overrides one or more of the artificial intelligence systems' assessments of trafficability or workability to ensure the trafficability or workability shown to the user is consistent with recently-provided feedback.

This can be accomplished in any number of ways. One approach is to replace the natural output of the artificial intelligence layer 143 with the trafficability or workability status the user most-recently provided, at least for some period of time after its submission. This may be applied to the field where the observation was taken, to all fields associated with the user, or any in a range of options in between. A more sophisticated approach may override the current trafficability or workability status in a fashion that trends back to the artificial intelligence layer's natural classification of the corresponding metric over time (i.e., to simply trend the status back to what the artificial intelligence systems indicates over time). The phase-out period of the override can be expedited if a weather event occurs that would be expected to have caused a sudden change in the field's status, such as a rainfall occurring on a field that had recently been reported as trafficable or workable.

Yet another approach to overriding the natural status of the artificial intelligence model 143 would be to change the interpretation of the model's output values. For instance, in a neural network it is common to normalize all of the input data to a range of −1 to 1, 0 to 1, or similar, in a continuous fashion, such that the inputs are all scaled similarly. Likewise, the training (feedback) data are typically also scaled in a similar fashion, such that (again, for instance) a value of −1 might be associated with poor reported workability, 0 with marginal reported workability, and 1 with good reported workability. Once trained on such data, and provided real-time or forecast input data scaled similarly to the training dataset, the neural network will produce an output value anywhere in the range −1 to 1. Values close to −1 would be interpreted as the artificial intelligence layers 143 indicating the field workability is likely poor, values near 0 would be interpreted as indicating the field workability is likely marginal, and values near 1 would be interpreted as indicating the field workability is likely good (with ‘gray’ areas in between). Accordingly, the system may be configured so as to interpret values greater (less than) 0 as indicative of good (poor) workability, regardless of whether applied to current or forecast input data 110. However, if the user provides fresh feedback data that can be matched to the artificial intelligence model 143 output by a simple translation of this threshold (for instance, changing the good/poor threshold from 0.0 to 0.2), this threshold for discriminating between poor and good conditions can then be altered as required. It can be altered for just the field the user provided the feedback on, fields in the vicinity, all fields on a farm, or all fields the user is associated with. It can also be relaxed back to a value of 0.0 over time, such that the field status as determined from the artificial intelligence models 143 both matches the most recently-provided feedback, but also relaxes back toward a threshold that is more representative of the collective feedback that has been accumulated over time.

The present invention contemplates that many different users and uses of this output data 150 are possible. Output data 150 from the various modeling paradigms described herein may therefore be used to perform several functions, either directly or through other systems, hardware, software, devices, services (such as the advisory services 180 described below), the agricultural decision support tool 160, and through one or more specific application programming interface (API) modules 170.

Regardless of the use or user, the output data may be tailored to provide specific management actions, whether it be in the form of a follow-on output from the tool 160, an advisory service 180, or API 170. For example, the present invention may provide a crop and soil conditions advisory 181 regarding a particular field or fields 102 that includes information beyond the indicators and forecasts described above. Such an advisory service 181 may provide analytics of damage reflected in a soil condition profile 145, such as for example an economic impact on a crop in the current growing season of particular soil conditions, or an economic impact from having to use certain field equipment or apply specific tillage practices to mitigate conditions discovered in soils in the particular field 102.

The present invention may also provide a contamination advisory service 182 for crops, soils, and groundwater or aquifers that is provided to owners of fields, growers of crops, and other responsible entities in relation to particular fields 102. Such a service may advise on tillage practices, for example where a profile 145 indicates possible contamination of soil beyond a specific acceptable range. For example, tillage of contaminated soils may easily spread airborne particles to other fields. Such an advisory 182 may therefore provide tillage practice analytics to manage contamination in the particular field 102 and beyond, such as models of the use of certain field equipment, and/or tillage timing and conduct.

Many additional agricultural advisories 180 are contemplated. Examples of advisory services 180 that include other agricultural management services are a tillage, planting and harvest advisory service 183, and a crop and soil nutrient and biological application advisory service 184, a pest and disease prediction advisory service 185, an irrigation advisory service 186, and a herd, feed, and rangeland management advisory service 187. Additional management services may include a regulatory advisory service 188. Clear Ag and other alerting is still another service 189 contemplated by the present invention.

All of these advisories 180 are possible with the output data 150, based on the input data 110 ingested. For example, a regulatory advisory service 188 may combine the outputs of the soil state assessment and artificial intelligence translation module 144 to produce an advisory based on the one or more profiles 145. Such an advisory may indicate that a soil has a high contamination risk of a substance that requires federal or state reporting. Another example of a regulatory advisory service 188 is an indicator of predicted environmental impact from runoff following delivery of a chemical treatment to soils.

In a further example, an irrigation advisory service 186 may consider indicators of field trafficability and workability, combined with the real-time observations in observed and reported data of field conditions and soil properties 119, to inform growers, landowners, or other responsible parties of irrigation mitigation actions, such as the positioning of flood, drip, and spray irrigation equipment, the timing of their use, and amounts of artificial precipitation to be applied. In still a further example, one or both of the herd, feed, and rangeland management advisory service 187 and the irrigation advisory service 186 may apply various types of data to provide information for irrigation requirements for achieving crop temperature and crop moisture thresholds for livestock herd management, in light of ground truth measurements and the soil condition information in one or more of the profiles 145.

It is to be noted that advisory services 180 may be provided as a specific outcome of the present invention where it is configured to provide all of the modular services described above in a packaged format, and the advisory services 180 may also be processed from output data 150 (either directly, or via the API modules 170, or as output from the agricultural decision support tool 160). It is further to be understood that many such advisory services 180 and API modules 170 are possible and are within the scope of the present invention.

The agricultural support tool 160 may be configured to customize the output data 150 for a specific use, or user, such as for example for a specific field, farm, crop, or piece of farm equipment, for a specific period of time. For example, the agricultural support tool 160 may be configured to generate an output signal, such as numerical indicator comprising an indication to proceed with a specified action, to be communicated directly to a specified piece of farm equipment operating in the field. Many examples of such customized uses are possible. In another example, a signal to one or more pieces of irrigation equipment may be generated to proceed with, change a direction or angle of application of, or stop artificial precipitation from being applied to the particular field 102, or to a specific area of a particular field 102.

The present invention may be executed by one or more processes for performing the field accessibility modeling framework 100, depending on the type of output desired. FIG. 2 is a flow diagram of a process 200 for assessing soil state and modeling soil compaction and structural capacity for field trafficability by agricultural equipment. In FIG. 2, the process 200 begins in step 202 by ingesting input data 110 and initializing the field trafficability model for assessing a soil state. The process 200 analyzes meteorological and climatological data 111 to profile expected weather conditions in the particular field 102. This may also performed in conjunction with one or more weather models. Regardless, the meteorological and climatological data 111 is used to diagnose and predict weather conditions in step 204, and the process 200 then pulls in additional input data 110 to simulate an expected soil response to the expected weather conditions in step 206 in an agronomic model 142 of physical and empirical characteristics impacting soil conditions in the particular field 102.

The present invention then proceeds with acquiring observations for training one or more artificial intelligence models 143, by obtaining observed and reported data of field conditions and soil properties 119 at least indicative of a temporal variability of soil moisture content, in step 208. These observations are associated with the input data 110, the expected soil response, and the expected weather conditions in step 210, and the one or more artificial intelligence models 144 are trained on the resulting associations in steps 212. Training in step 212 enables the artificial intelligence layer 144 of the present invention to continually perform combined analyses of input data 110, the expected soil response, and expected weather conditions for the particular field 102 in a plurality of mathematical and statistical analyses to perform the assessment of a soil state in the particular field 102, as discussed further herein.

The soil state assessment 144 from the approach described above is then translated at step 214 into a profile 146 of soil compaction and structural capacity to permit access to and support for agricultural equipment. This profile 146 is used by the field accessibility modeling framework 100 and process 200 to generate field trafficability indicators in step 216, which represent output data 150 of the present invention. The process 200 also includes step 218, which is a comparison of the profile 146 to the observations in observed and reported data 119. In steps 218, where a difference in the profile 146 and actual measurements in the observed and reported data 119 exceeds a certain threshold or variance, the process may forcefully adapt the indicators of field trafficability, either temporarily or permanently, to match actual, real-time, or current conditions experienced in the particular field 102.

FIG. 3 is a flow diagram of a process 300 for assessing soil state and modeling soil tilth and mechanical strength for field workability for various cultivation actions. In FIG. 3, the process 300 initiates at step 302 with intake of input data 110. The field workability modeling paradigm of this aspect of the present invention is initialized at this step 302 for assessment of a soil state. The process 300 analyzes meteorological and climatological data 111 to profile expected weather conditions in the particular field 102. This may also performed in conjunction with one or more weather models. Regardless, the meteorological and climatological data 111 is used to diagnose and predict weather conditions in step 304, and the process 200 additional input data 110 to simulate an expected soil response to the expected weather conditions in step 306 in an agronomic model 142 of physical and empirical characteristics impacting soil conditions in the particular field 102.

The process 300 proceeds with acquiring observations for training one or more artificial intelligence models 143, by obtaining observed and reported data of field conditions and soil properties 119 at least indicative of a temporal variability of soil moisture content, in step 308. These observations are associated with the input data 110, the expected soil response, and the expected weather conditions in step 210, and the one or more artificial intelligence models 144 are trained on the resulting associations in steps 312. Training in step 312 enables the artificial intelligence layer 144 of the present invention to continually perform combined analyses of input data 110, the expected soil response, and expected weather conditions for the particular field 102 in a plurality of mathematical and statistical analyses to perform the assessment of a soil state in the particular field 102, as discussed further herein.

The soil state assessment 144 from the approach described above is then translated at step 314 into a profile 147 of soil tilth and mechanical strength, which is indicative of the field's workability for cultivation activity. This profile 147 is used by the field accessibility modeling framework 100 and process 300 to generate field workability indicators 152 in step 316, which represent another form of the output data 150 of the present invention. The process 200 also includes step 318, which is a comparison of the profile 147 to the observations in observed and reported data 119. In step 318, where a difference in the profile 147 and actual measurements in the observed and reported data 119 exceeds a certain threshold or variance, the process may forcefully adapt the indicators 152 of field workability, either temporarily or permanently, to match actual, real-time, or current conditions in the particular field 102.

FIG. 4 is a flow diagram of a process 400 for assessing soil state and one or more windows of a field's suitability for agricultural activity owing to freezing and thawing cycles in soil. The process 400 models anticipated cycles of freezing and thawing to generate forecasts 153 representing the suitability windows.

At step 402, the process 400 ingests external input data 110 and initializes the modeling paradigm for assessing a soil state and the suitability windows for agricultural activity according to this aspect of the present invention. At step 404, the process 400 forecasts time-varying expected weather conditions from meteorological and climatological data 111, at a geographical location(s) that at least include the particular field 102. At step 406, the present invention simulates an expected soil response to the external input data 110 by application of that input data 110 to the agricultural model 142 of one or more physical and empirical characteristics impacting soil conditions in the particular field 102.

The process 400 includes obtaining observations of actual, current or real-time field and soil conditions in reported soil information 119 that is indicative of soil freezing and thawing cycles at step 408, and at step 410 applies this data 119 to identify relationships between reported soil information 119, the expected soil response, and the other external input data 110. The artificial intelligence layer 143 proceeds in step 412 by comparing reported soil information 119 with the other external input data 110 and the expected soil response at the specific geo-location and time of each data point identified in the reported soil information 119. At step 414, the process builds a soil condition profile 148 representing anticipated freezing and thawing cycles for the particular field 102, and forecasts suitability windows 153 at step 416 for agricultural activity from the profile 148.

The system architecture and processes of the present invention may be thought of alternatively as comprising three main sections, which include a set of application programming interfaces, one or more field accessibility modules, and a database layer indicating at least in part where accessibility information is derived from for performing the multi-part approach. The field accessibility modules may collectively comprise the data processing modules 132 and may further include, in addition to those mentioned herein, an artificial intelligence accessibility module, an integrated accessibility module, a feedback capture module, an overriding accessibility module, an override reset module, and an artificial intelligence training module. Regardless, the data processing modules 132 described herein are configured to access land surface model data, weather data, crop, soil and field data, and associated metadata via the database layer and from one or more application programming interfaces, or modules configured to execute such APIs. Additional data may also be accessed from one or more database locations, as needed by the various modeling paradigms described herein. Data may be accessed, ingested, retrieved, requested, acquired or obtained by the plurality of data processing modules 132 either automatically, an on as-needed basis, or an on-load basis.

Models that are based on the application of artificial intelligence to the problems identified above are able to automatically construct appropriate relationships between relevant factors, variables, and properties based on data alone, without the need for a full scientific understanding of the underlying processes. For instance, if predictive factors known to be related to a particular outcome are understood and measured along with the actual outcomes in real-world situations, artificial intelligence techniques can be used to ‘train’ or construct a model that will relate the more readily-available predictors to the ultimate outcomes, without any specific a priori knowledge as to the form of those relationships. Therefore, introducing artificial intelligence, or AI, systems between the weather data, land surface model outputs, and the consumer of this information, in addition to related crop, soil and field characteristics, enables the automatic identification of the relationships between the available data resources and the feedback observations of the information consumer/user.

For instance, given a data collection and communication device, the user can be provided an indication of the diagnosed trafficability or workability of the soils within a particular field. This indication may be formulated on expert-based relationships between the weather and land surface model data, in addition to related crop, soil and field characteristics, and the expected trafficability or workability, or it may be based on a translation of the weather and land surface model data, and related crop, soil and field characteristics, by artificial intelligence systems that have been developed through evaluation of previous user-provided indications of trafficability or workability relative to the weather and land surface model data, in addition to the related characteristics, at those same times and locations.

Artificial intelligence applications may be hindered by the large quantity of data needed in order for the model(s) employed to be able to fully explore and define the nature of the relationships, as well as the lack of ability to later incorporate new sources of predictive data into an existing model. However, overly-simplified models (in terms of the degrees of freedom the model has to adapt to the data) may limit the ability of an artificial intelligence model to fully replicate the complex relationships that might exist between the factors that impact a particular outcome and the actual outcome itself. Conversely, overly-complex artificial intelligence models require ever-larger datasets in order to be developed, in part because of the risk of over-fitting the model to sample data, which may not provide a thorough sampling of the underlying data and processes, simply because of the number of degrees of freedom a complex artificial intelligence model can have available to fit the specific sample data.

In light of these considerations, and in the presence of finite data, a combined approach for simulating the relationships between predictive data and observable outcomes provides a solution to the problems above. The general nature of the relationships can be quantified with a physical model, with an artificial intelligence model then applied to a combination of the predictive data and physical model outputs to better simulate the ultimate outcomes. This approach permits the better-understood portions of the problem at hand to be modeled using the physical model, thereby diminishing the degrees of freedom required in the artificial intelligence model (and, accordingly, reducing the quantity of real-world data needed to develop the artificial intelligence model). As the size of the available datasets grow, the benefits of this two-step approach relative to a single-step approach based solely on artificial intelligence provide intrinsic value to the physical model by enabling more readily-identifiable insight into the nature of the complex interactions that may be involved.

In the case of field trafficability and workability, the data required to reliably model some of the underlying processes and problems has historically been difficult to obtain. While many of the key predictive factors and outcomes are routinely measured and observed in production agriculture (though perhaps in indirect and/or ad hoc manners), they are rarely reported into a centralized repository of data that could be used to develop models that simulate the relevant relationships. Further, the mere act of collecting and reporting this data does not in itself provide the ability to develop models based on the data. Observations of the more readily-obtainable predictive data associated with each of these measurements must also be captured, and observations that relate to one another in terms of location or time should be stored in such a way that permits them to be tied together as appropriate to provide more meaningful insight into a problem than a single observation can provide by itself (e.g., a time-series of moisture samples from the same field may be more revealing than a completely random set of unrelated samples from various locations and times).

Accordingly, the field accessibility modeling framework 100 of the present invention may include, in one embodiment thereof, a database layer that enables storage and organization of such observations. This database layer is configured to accept, ingest, retrieve, or otherwise obtain information that includes predictive metadata, weather data, land surface model data, related crop, soil and field characteristics, and feedback (user-indicated or automatically communicated) as noted herein, and pool such information so that they can be related to one another in an efficient manner in terms of location or time.

While the discussed models and methods provide the opportunity to substantially advance the state of the art in terms of planning and managing agricultural operations, it is notable that there will still potentially be user- or locality-based biases in the observations and predictive data that are available to develop these models. Some of these biases may represent nothing more than differences in perception (where subjective feedback is accepted), while others may be due to biases in the instrument(s) used to collect more quantitative observations, and even others may be due to variability in factors associated with the crop or farm operation that are outside of the realm of what is being collected in terms of metadata (for instance, the design of the particular equipment being used can impact both the field trafficability and workability for a given operation). Because of this, it can be useful to develop both generalized artificial intelligence models, using all available data and metadata, but also to develop localized- or user-specific artificial intelligence models tailored to a particular location or user. Doing so reliably requires a substantial amount of data be provided for that particular subsample of data, but given an adequately-sized dataset the resulting highly-localized or -personalized models will often yield information that is well-suited to the particular location or user that provided the original data.

Whether the present indication of the trafficability or workability of a field is correct or not (in the eyes of the user), the user can be furnished with a real-time feedback mechanism by which he or she can validate or correct that present indication of the trafficability or workability. Each time this information is provided, the associated predictive metadata, weather data, and land surface model data, in addition to the related crop, soil and field characteristics, can be captured and stored alongside the user-indicated condition. This information can then be pooled over time, either within a field or across fields, and for a user or across a pool of users, to serve as the training dataset for the development of AI systems (using, for example, neural networks, decision trees, or k-nearest neighbor models). Thus, the artificial intelligence systems contemplated in the present invention are capable of learning the relationships between workability, trafficability, and the input weather and soil condition data it has to work with at any given time and location.

While a new user will be largely dependent on a predefined ‘community’ model for translating this weather and soil condition data into a more useable trafficability or workability indication, as the pool of data grows for a particular user, user community, farm, farm group, or field, the artificial intelligence systems can be automatically directed to develop more-personalized indications of trafficability or workability for that particular user, user community, farm, farm group, or field. This can be done, for example, by requiring a minimum number of user-provided feedback/input data pairs in order to proceed with the (automated) development of a personalized artificial intelligence model. For instance, if 100 feedback/input data pairs are required to develop a particular personalized AI model, and the user has only provided 10 such pairs so far, the other 90 pairs can be selected from either a random or targeted subsampling of the pairs submitted by the larger community. As the user continues to provide more feedback pairs, the model can become increasingly adjusted to the specific data the user has provided. The same holds true at the farm and field level in addition to the user level, i.e. separate artificial intelligence models can be automatically developed for each farm and/or field as sufficient data is captured from that farm or field.

In this manner, the consumer of the field accessibility information is provided several benefits. As a new user, he or she is provided the benefit of an artificial intelligence model that amounts to an average translation (by the entire user community) of the weather and soil condition data into trafficability or workability information (i.e., it will be based on the average trafficability or workability reported by other users, relative to the associated weather and soil condition data). As the user continues to provide feedback to the system, the number of data pairs associated with the user, and the user's farms and fields, continues to grow, thereby permitting the automated, ongoing redevelopment of artificial intelligence models specific to each user, user community, farm, farm group, and/or field. In this manner, the entire system can ‘learn’ how to associate the basis weather and soil condition data, in addition to the related crop and field characteristics, to the reported trafficability and/or workability, which are in turn functions of the user's equipment, farming practices, perceptions, unrepresented environmental properties, crops, etc. Thus, the trafficability and workability metrics within the field accessibility framework become highly personalized.

Further, such an artificial intelligence model implicitly yields information as to the importance of the various input weather and soil condition data elements through, for example if using a neural network, the resulting weighting systems between inputs, the layers of activation functions in the neural network, and the model output(s). This information can be used to identify which factors are particularly important or unimportant in the associated process, and thus help to target ways of improving the model over time. It should be noted that while the application of a neural network model as a component of the artificial intelligence systems is used in some of the examples contained herein, these examples are not intended to be limiting as to the form of the artificial intelligence systems in the present invention.

The present invention contemplates no limitation on the types of artificial intelligence system (e.g., supervised learning, reinforcement learning, clustering, classification), nor on the number or combination of these systems within or relating to the modeling performed. For example, a neural network in conjunction with particle swarm optimizer for faster training of the neural network may be used for the synthesis of weather and soil data into a single numeric value, while a multiple classification k-nearest neighbor system correlates and classifies the field accessibility index into a human-friendly metric (such as ‘good’, ‘poor’, or ‘marginal’). In another example, one may use one or more artificial intelligence systems to produce a field accessibility index and one or more AI systems to feed additional analyses and services such as field operations pertaining to field accessibility for spring/summer/fall tillage, spring/summer/fall sowing or planting, chemical applications, row crop cultivating, and harvesting.

The artificial intelligence systems may also be capable of automatically recognizing large deviations from the norms, commonly called outliers, and handling them as such: a) reporting them to a logging system for later analyses, b) dropping the outlier from the dataset(s), c) upon receiving a user-provided feedback, issuing a notice of norm deviation or challenge on the certainty of the observation, or d) accepting the data, but may provide additional analyses as a result of incorporating the outlier(s) into the dataset(s) and thus the model(s). The outlier feedback, over time and with enough deviations that positively correlate over a small region, will alter the future behavior of one or more models in a given vicinity due to the locality of feedback and how the AI systems treat the location of the feedbacks and data within the datasets.

The optimization of the interpretation of the field accessibility output values may be performed in another artificial intelligence system that adapts more quickly to user provided feedback than either the community models or localized models. The system may therefore utilize one of the above options or it may use another AI system that examines the previous user feedbacks and the current user feedback to find interpretation values that satisfy, using the previous field accessibility output values, the current user feedback's desired (interpreted) result. The optimization of the interpretation of the output values, as mentioned above, allows “corrective” measures to be taken to tailor the field accessibility output to more readily match the user's observed conditions while also adapting the field accessibility output of near-term subsequent timeframes to benefit from the user's past and current feedback. For example, if the user provides feedback that the field is marginal and not poor as was indicated by the field accessibility system, the interpretation values optimization system would examine the field accessibility output, the threshold for marginal, and previous feedbacks. If, in this example, the field accessibility output was 0.1 at the time of the analysis and the threshold for the marginal interpretation value was 0.15 at the time, the interpretation values optimization system may, using artificial intelligence techniques, optimize the marginal interpretation value to fall below the field accessibility output value. The result of the optimization to the interpretation values allows for future, whether short-term or long-term, adaptability of a field's actual conditions to the field accessibility output, whether using one or more community models, hybrid community/localized models, or localized models. The optimization process may occur upon receiving a new feedback, updating an existing feedback, or simply by requesting a new field accessibility output.

Additional field characteristics, such as surface and subsurface drainage and irrigation properties, may also be used within the land surface models and the artificial intelligence systems to greatly improve the accuracy and prediction of soil conditions. As noted above, these types of field characteristics play a role in defining the structural stability, strength, and water-retention properties of agricultural topsoils, and resulting agricultural productivity of the soils within a field, for example following a precipitation or irrigation event.

Further, additional datasets, whether generated internally, user-provided, instrument-derived, or otherwise obtained via a third party (such as a business or government entity), such as elevation data, field soil types, spatial data on soil types within a region or field, data on field operations per crop, crop/plant growth characteristics as they pertain to the altering of soil conditions, previous or current watershed analyses, network flow analyses, and more, may noticeably or significantly improve the accuracy, resolution, availability of variables, or quality of the analyses performed on the data pertaining to a field, region, or any combination of users, fields, farms, or area bounds (field, farm, township, parish, county, state, country, etc.). These characteristics and datasets are commonly referred to as related crop and field characteristics.

It should further be noted that while much of the preceding discussion has focused on field trafficability and workability measures based on soil moisture conditions, this is by no means intended to limit the scope of the present invention. For instance, on the fringes of the growing season, it is not uncommon for soils to freeze during the overnight hours or during spells of cold weather. Frozen soils are every bit as adverse to field workability as excess moisture, and—in the case of frozen soils in the autumn months—can lead to an abrupt or premature end to post-harvest tillage operations (or to the harvest operation itself, if for a root-based crop). While land surface models are able to predict soil temperatures and the processes of freezing and thawing of soils in layers throughout the depth of the soil profile, the modeling of these processes is also subject to field-level variations in residue, elevation, moisture, and other factors that may not be adequately represented in the model. As such, as the user begins to observe the daily freeze/thaw cycle on the fringes of the growing season, and provides input on the times at which the soil was noted to be frozen and thawed, the AI systems can learn to associate these occurrences with more readily-available land surface model data, thereby permitting a more accurate prediction of freeze/thaw cycles in the coming days and weeks.

It is therefore contemplated that many applications and modifications of the field accessibility modeling framework 100 described herein are possible, and within the scope of the present. These at least include training and applying AI-based systems to translate weather and soil condition data, in addition to related crop and field characteristics, into field trafficability or workability metrics based on validating and corrective feedback received from a community of users, a user, a farm, a group of farms, and/or a field over one or more combinations of regions and sub-regions. They also include training and applying AI-based systems to translate weather and soil condition data, in addition to related crop and field characteristics, into field trafficability or workability metrics based on past and current data collected from on-board data collection systems in farm-related operations—such an application utilizes information on the periods during which various field operations were able (or not able) to be performed as a surrogate for direct feedback.

Other applications of the field accessibility modeling framework 100 include using farm- and field-specific feedback, either provided by a user or collected automatically from farm equipment, to create farm- and field-specific indicators of field accessibility or workability that are tailored to the specific equipment utilized or to a specific field operation perform on the farm and the farming practices utilized on the particular farm or field. Another application of the field accessibility modeling framework 100 includes training and applying AI-based systems to translate weather and soil condition data, in addition to related crop and field characteristics, into tailored indications of expected periods of thawed or frozen soils, and yet another application includes using weather and soil condition data, possibly including AI-based translation systems, to develop metrics that quantify the impacts of various field of operations at various times, such as indicators of the suitability of soil conditions for maintenance of desired soil structure, indicators for the risk of compaction through the performance of field operations, indicators of the risk that soil moisture and/or temperature conditions will fall above or below threshold values considered suitable for seed germination, and indicators of the likely effectiveness of tillage operations for weed control based on the combination of soil and atmospheric conditions, in addition to related crop and field characteristics.

The field accessibility modeling framework 100 may also be used to develop a high resolution drainage basin analysis that allows for much more precise predictions of soil conditions based upon natural and artificial drainage and irrigation properties and user- or instrument-provided feedback. This may include using one or more of weather and soil condition data, user-provided field characteristics, such as surface and subsurface drainage or irrigation systems, elevation data (such as light detection and ranging [LIDAR]), whether or not user-provided, water flow, catchment, and lake flooding models, and outputs from one or more AI-based systems.

The systems and methods of the field accessibility modeling framework 100 may be implemented in many different computing environments 130. For example, they may be implemented in conjunction with a special purpose computer, a programmed microprocessor or microcontroller and peripheral integrated circuit element(s), an ASIC or other integrated circuit, a digital signal processor, electronic or logic circuitry such as discrete element circuit, a programmable logic device or gate array such as a PLD, PLA, FPGA, PAL, and any comparable means. In general, any means of implementing the methodology illustrated herein can be used to implement the various aspects of the present invention. Exemplary hardware that can be used for the present invention includes computers, handheld devices, telephones (e.g., cellular, Internet enabled, digital, analog, hybrids, and others), and other such hardware. Some of these devices include processors (e.g., a single or multiple microprocessors), memory, nonvolatile storage, input devices, and output devices. Furthermore, alternative software implementations including, but not limited to, distributed processing, parallel processing, or virtual machine processing can also be configured to perform the methods described herein.

The systems and methods of the present invention may also be partially implemented in software that can be stored on a non-transitory storage medium, executed on programmed general-purpose computer with the cooperation of a controller and memory, a special purpose computer, a microprocessor, or the like. In these instances, the systems and methods of this invention can be implemented as a program embedded on personal computer such as an applet, JAVA.RTM or CGI script, as a resource residing on a server or computer workstation, as a routine embedded in a dedicated measurement system, system component, or the like. The system can also be implemented by physically incorporating the system and/or method into a software and/or hardware system.

Additionally, the data processing functions disclosed herein may be performed by one or more program instructions stored in or executed by such memory, and further may be performed by one or more modules configured to carry out those program instructions. Modules are intended to refer to any known or later developed hardware, software, firmware, artificial intelligence, fuzzy logic, expert system or combination of hardware and software that is capable of performing the data processing functionality described herein.

The foregoing descriptions of embodiments of the present invention have been presented for the purposes of illustration and description. It is not intended to be exhaustive or to limit the invention to the precise forms disclosed. Accordingly, many alterations, modifications and variations are possible in light of the above teachings, may be made by those having ordinary skill in the art without departing from the spirit and scope of the invention. It is therefore intended that the scope of the invention be limited not by this detailed description. For example, notwithstanding the fact that the elements of a claim are set forth below in a certain combination, it must be expressly understood that the invention includes other combinations of fewer, more or different elements, which are disclosed in above even when not initially claimed in such combinations.

The words used in this specification to describe the invention and its various embodiments are to be understood not only in the sense of their commonly defined meanings, but to include by special definition in this specification structure, material or acts beyond the scope of the commonly defined meanings. Thus if an element can be understood in the context of this specification as including more than one meaning, then its use in a claim must be understood as being generic to all possible meanings supported by the specification and by the word itself.

The definitions of the words or elements of the following claims are, therefore, defined in this specification to include not only the combination of elements which are literally set forth, but all equivalent structure, material or acts for performing substantially the same function in substantially the same way to obtain substantially the same result. In this sense it is therefore contemplated that an equivalent substitution of two or more elements may be made for any one of the elements in the claims below or that a single element may be substituted for two or more elements in a claim. Although elements may be described above as acting in certain combinations and even initially claimed as such, it is to be expressly understood that one or more elements from a claimed combination can in some cases be excised from the combination and that the claimed combination may be directed to a sub-combination or variation of a sub-combination.

Insubstantial changes from the claimed subject matter as viewed by a person with ordinary skill in the art, now known or later devised, are expressly contemplated as being equivalently within the scope of the claims. Therefore, obvious substitutions now or later known to one with ordinary skill in the art are defined to be within the scope of the defined elements.

The claims are thus to be understood to include what is specifically illustrated and described above, what is conceptually equivalent, what can be obviously substituted and also what essentially incorporates the essential idea of the invention.

In the foregoing description, certain terms have been used for brevity, clearness and understanding; but no unnecessary limitations are to be implied therefrom beyond the requirements of the prior art, because such terms are used for descriptive purposes and are intended to be broadly construed. Moreover, the description and illustration of the inventions is by way of example, and the scope of the inventions is not limited to the exact details shown or described.

Although the foregoing detailed description of the present invention has been described by reference to an exemplary embodiment, and the best mode contemplated for carrying out the present invention has been shown and described, it will be understood that certain changes, modification or variations may be made in embodying the above invention, and in the construction thereof, other than those specifically set forth herein, may be achieved by those skilled in the art without departing from the spirit and scope of the invention, and that such changes, modification or variations are to be considered as being within the overall scope of the present invention. Therefore, it is contemplated to cover the present invention and any and all changes, modifications, variations, or equivalents that fall with in the true spirit and scope of the underlying principles disclosed and claimed herein. Consequently, the scope of the present invention is intended to be limited only by the attached claims, all matter contained in the above description and shown in the accompanying drawings shall be interpreted as illustrative and not in a limiting sense.

Having now described the features, discoveries and principles of the invention, the manner in which the invention is constructed and used, the characteristics of the construction, and advantageous, new and useful results obtained; the new and useful structures, devices, elements, arrangements, parts and combinations, are set forth in the appended claims.

It is also to be understood that the following claims are intended to cover all of the generic and specific features of the invention herein described, and all statements of the scope of the invention which, as a matter of language, might be said to fall therebetween.

1. A method of diagnosing and predicting in-field soil conditions for assessing a field's trafficability for performance of one or more specific field operations, the method comprising:
diagnosing and predicting weather conditions impacting soil conditions in a particular field by profiling expected weather conditions for the particular field from at least one of in-situ weather data, remotely-sensed weather data, and modeled weather data;
developing an agronomic model of one or more physical and empirical characteristics impacting soil conditions in the particular field to predict a soil's suitability for the performance of one or more specific field operations comprising cultivation activity that includes at least one of tillage, irrigation, sowing, seeding, planting, cutting, windrowing and harvesting, the soil's suitability predicted by:
simulating an expected soil condition response in the particular field from crop and soil characteristics in the particular field and the diagnosed and predicted weather conditions;
associating one or more observations of field conditions and soil properties that are indicative of variability in the soil's suitability for the performance of the one or more specific field operations, from at least one of the particular field and one or more other fields associated with the particular field, at one or more times, with the diagnosed and predicted weather conditions, simulated expected soil condition response, and the crop and soil characteristics;
instantiating one or more neural networks configured to identify relationships between predictor data points in the crop and soil characteristics, the diagnosed and predicted weather conditions, and the expected soil condition response, and data points in associated outcomes from the one or more observations of field conditions and soil properties to adjust one or more initial simulations of the expected soil condition response, by training the one or more neural networks with data points taken at prior times from the particular field and at least one field associated with the particular field, and applying the one or more neural networks to predict the expected soil condition response and soil property outcomes at current and future times in either the particular field or fields associated with the particular field;
translating a combined analysis of the diagnosed and predicted weather conditions, the expected soil condition response, and predicted field condition and soil property outcomes from the one or more neural networks into a trafficability profile of the soil compaction and structural capacity for access by and support for agricultural equipment for the performance of the one or more specific field operations, the trafficability profile representing a predicted soil suitability for the performance of the one or more specific field operations; and
initiating a forced adaptation module specially configured to enhance one or more outputs associated with the trafficability profile by overriding the one or more outputs associated with the trafficability profile when a variance indicator exceeds one or more threshold index values, wherein the forced adaptation module enhances the one or more outputs associated with the trafficability by replacing one or more outputs associated with the trafficability with one or more values obtained from user threshold data.

2. The method of claim 1, further comprising training the one or more neural networks with the one or more observations of field conditions and soil properties to continually perform the combined analysis of the diagnosed and predicted weather conditions, the expected soil condition response, the crop and soil characteristics, the predicted field condition and soil property outcomes, and the data points in associated outcomes from the one or more observations.

3. The method of claim 1, further comprising comparing the trafficability profile to the one or more observations of field conditions and soil properties, and forcing the one or more indicators to temporarily adapt to the one or more observations of field conditions and soil properties for a specified period of time.

4. The method of claim 1, further comprising comparing the trafficability profile to the one or more observations of field conditions and soil properties, and forcing the one or more indicators to permanently adapt to the one or more observations of field conditions and soil properties.

5. The method of claim 1, wherein the one or more observations of field conditions and soil properties are at least one of ground truth feedback of sampled soil moisture content and measurements of crop moisture content, data captured by sensors on-board agricultural equipment, positional data received from transmitters installed on agricultural equipment, and satellite imagery data of a geographical area comprising the particular field.

6. The method of claim 1, wherein the agronomic model includes a land surface model.

7. The method of claim 1, wherein the one or more indicators include at least one of a numerical value representing field trafficability, a non-numerical index of field trafficability, and an indicator of soil suitability for agricultural equipment in the particular field, and wherein the one or more indicators further comprise at least one of an indicator of a risk of soil compaction, an indicator of soil temperature over time, an indicator of soil moisture content over time, an indicator of soil productivity degradation from a compaction of soil, an indicator of soil structure damage from excessive density inhibiting plant root penetration and distribution, an indicator of excessive soil surface residue, and an indicator of organic matter content level.

8. The method of claim 9, further comprising generating, as output data, one or more indicators customized to a specific field, a specific crop, or specific item of agricultural equipment.

9. The method of claim 1, further comprising applying the trafficability profile of the soil compaction and structural capacity for access to and support for agricultural equipment to a decision support tool configured to provide one or more advisories of the field trafficability to a user.

10. The method of claim 1, wherein the one or more threshold index values is defined by a user prior to a first generated trafficability profile of the soil compaction and structural capacity for access by and support for agricultural equipment for the performance of the one or more specific field operations.

11. The method of claim 1, further comprising generating the variance indicator, wherein the forced adaptation module compares the one or more values associated with the trafficability profile of the soil compaction and structural capacity for access by and support for agricultural equipment for the performance of the one or more specific field operations with feedback data and generating the variance indicator.

12. A system of diagnosing and predicting in-field soil conditions for assessing field trafficability for performance of one or more specific field operations, comprising:
a computing environment including at least one computer-readable storage medium having program instructions stored therein and a computer processor operable to execute the program instructions to model field trafficability within a plurality of data processing modules, the plurality of data processing modules including:
a weather modeling module configured to diagnose and predict weather conditions impacting soil conditions in a particular field, by profiling expected weather conditions for the particular field from at least one of in-situ weather data, remotely-sensed weather data, and modeled weather data;
an agronomic model of one or more physical and empirical characteristics impacting soil conditions in the particular field to predict a soil's suitability for a performance of one or more specific field operations comprising cultivation activity that includes at least one of tillage, irrigation, sowing, seeding, planting, cutting, windrowing and harvesting, the agronomic model configured to 1) simulate an expected soil condition response to the diagnosed and predicted weather conditions, and to crop and soil characteristics for the particular field, 2) associate one or more observations of field conditions and soil properties that are indicative of variability in the soil's suitability for the performance of the one or more specific field operations, from at least one of the particular field and one or more other fields associated with the particular field at one or more times, with the diagnosed and predicted weather conditions, simulated expected soil condition response, and crop and soil characteristics, 3) instantiate one or more neural networks configured to identify relationships between predictor data points in the crop and soil characteristics, the diagnosed and predicted weather conditions, and the expected soil condition response, and data points in associated outcomes from the one or more observations of field conditions and soil properties to adjust one or more initial simulations of the expected soil condition response, by training the one or more neural networks with data points taken at prior times from the particular field and at least one field associated with the particular field, and applying the one or more neural networks to predict the expected soil condition response and soil property outcomes at current and future times in either the particular field or fields associated with the particular field; 4) perform a combined analysis of the diagnosed and predicted weather conditions, the expected soil condition response, and predicted field condition and soil property outcomes from the one or more neural networks to model a trafficability profile of soil compaction and structural capacity for access by and support for agricultural equipment for the performance of the one or more specific field operations, the trafficability profile representing a predicted soil suitability for the performance of the one or more specific field operations, 5) match user-provided feedback data to outputs of the one or more neural networks to refine a threshold representing the combined analysis between conditions favoring the performance of the one or more specific field cultivation operations, and not favoring the performance of the one or more specific field cultivation operations, based on a collection of the user-provided feedback data, wherein the refined threshold scales temporally respective to when the feedback is provided, the scaling being from an initial threshold state to a threshold state that is representative of a collective feedback of the system; and 6) apply the refined threshold to the one or more neural networks to augment the predicted soil suitability by creating user-optimized categorical trafficability predictions based on the collection of the user-provided feedback data; and
a forced adaptation module specially configured to enhance one or more outputs associated with the trafficability profile by overriding the one or more outputs associated with the trafficability profile when a variance indicator exceeds one or more threshold index values, and wherein the forced adaptation module enhances the one or more outputs associated with the trafficability by replacing one or more outputs associated with the trafficability with one or more values obtained from user threshold data,
wherein the one or more specific field operations are initiated from the trafficability profile for the particular field, and wherein a user performs the one or more specific field operations based on an augmented predicted soil suitability.

13. The system of claim 12, wherein the agronomic model is further configured to force one or more indicators of field trafficability identified from the trafficability profile to temporarily adapt to the one or more observations of field conditions and soil properties for a specified period of time.

14. The system of claim 12, wherein the agronomic model is further configured to force one or more indicators of field trafficability identified from the trafficability profile to permanently adapt to the one or more observations of field conditions and soil properties,

15. The system of claim 12, wherein the one or more observations of field conditions and soil properties are at least one of ground truth feedback of sampled soil moisture content and measurements of crop moisture content, data captured by sensors on-board agricultural equipment, positional data received from transmitters installed on agricultural equipment, and satellite imagery data of a geographical area comprising the particular field.

16. The system of claim 12, wherein the agronomic model includes a land surface model.

17. The system of claim 12, wherein the one or more indicators include at least one of a numerical value representing field trafficability, a non-numerical index of field trafficability, and an indicator of soil suitability for agricultural equipment in the particular field, and wherein the one or more indicators further comprise at least one of an indicator of a risk of soil compaction, an indicator of soil temperature over time, an indicator of soil moisture content over time, an indicator of soil productivity degradation from a compaction of soil, an indicator of soil structure damage from excessive density inhibiting plant root penetration and distribution, an indicator of excessive soil surface residue, and an indicator of organic matter content level.

18. The system of claim 17, further comprising generating, as output data, one or more indicators customized to a specific field, a specific crop, or specific item of agricultural equipment,

19. The system of claim 12, wherein the one or more threshold index values is defined by a user prior to a first generated trafficability profile of the soil compaction and structural capacity for access by and support for agricultural equipment for the performance of the one or more specific field operations.

20. The system of claim 12, further comprising generating the variance indicator, wherein the forced adaptation module compares the one or more values associated with the trafficability profile of the soil compaction and structural capacity for access by and support for agricultural equipment for the performance of the one or more specific field operations with feedback data and generating the variance indicator.
